(19) United States
(12) Patent Application Publication
(10) Pub. No.: US 2026/0221957 A1
(43) Pub. Date: Jul. 30, 2026

(54) MULTILAYER BODY, ELEMENT INCLUDING THE MULTILAYER BODY, AND METHOD OF PRODUCING THE MULTILAYER BODY

(71) Applicant: JAPAN SCIENCE AND TECHNOLOGY AGENCY, Kawaguchi-shi Saitama (JP)

(72) Inventors: Shinya YAMADA, Toyonaka-shi, Osaka (JP); Kohei HAMAYA, Toyonaka-shi, Osaka (JP); Takamasa USAMI, Toyonaka-shi, Osaka (JP); Tomoyasu TANIYAMA, Nagoya-shi, Aichi (JP); Sachio KOMORI, Nagoya-shi, Aichi (JP)

(73) Assignee: JAPAN SCIENCE AND TECHNOLOGY AGENCY, Kawaguchi-shi Saitama (JP)

(21) Appl. No.: 19/145,044

(22) PCT Filed: Jan. 10, 2024
(86) PCT No.: PCT/JP2024/000320

§ 371 Date: Jul. 1, 2025

(30) Foreign Application Priority Data
Feb. 14, 2023 (JP) 2023-021057

(51) Int. Cl. H03H 9/22; H01Q 13/00; H03H 3/06

(52) U.S. Cl. CPC H03H 9/22; H03H 3/06; H01Q 13/00

(57) ABSTRACT

A multilayer body, an element including the multilayer body, and a method of producing the multilayer body are provided. A multilayer body includes a piezoelectric layer made of a crystal of an oxide having piezoelectricity, a metal layer, and a magnetic layer made of a crystal of a Heusler alloy, which is a ferromagnetic material. The piezoelectric layer, the metal layer, and the magnetic layer are stacked in this order.

### TECHNICAL FIELD

The present disclosure relates to a multilayer body, an element including the multilayer body, and a method of producing the multilayer body.

### BACKGROUND

For example, as disclosed in Patent Literature (PTL) 1, it is known that when vibration, such as acoustic waves, is injected into magnetic materials, spin waves (also referred to as spin currents or magnons) are generated in the magnetic materials. Elements utilizing spin waves generated in this manner are also known.

PTL 1 discloses an acoustic wave-to-spin current conversion element. This element has an acoustic wave generation member, a magnetic member that generates spin currents by an acoustic wave from the acoustic wave generation member, an inverse spin Hall effect member into which the spin currents generated by the magnetic member are injected, and a magnetic field application means that regulates the magnetization direction of the magnetic member. In this element, the acoustically induced spin currents are taken out of the inverse spin Hall effect member. Specifically, the spin currents are generated by the acoustic wave that is incident perpendicularly on the magnetic member, and the spin currents are pumped from the interface into the inverse spin Hall effect member in a perpendicular direction. PTL 1 also discloses that when the acoustic wave is injected into the magnetic member, the acoustically induced spin currents are generated in the magnetic member.

PTL 2 discloses a magnetic thin film, a magnetoresistance effect element using the same, and a magnetic device. This magnetic thin film includes a substrate and a Co₂Fe(Si₁₋ₓAlₓ) thin film formed on the substrate, wherein the Co₂Fe(Si₁₋ₓAlₓ) thin film has the L2₁ or B2 structure and 0<x<1. A tunneling magnetoresistance (TMR) effect element and a giant magnetoresistance (GMR) effect element using such magnetic thin films exhibit large TMR and GMR at room temperature, with low electric current and under low magnetic fields. In this magnetic thin film, a buffer layer may be interposed between the substrate and the Co₂Fe(Si₁₋ₓAlₓ) thin film. The buffer layer may be made of at least one of Cr, Ta, V, Nb, Ru, Fe, an FeCo alloy, or a full Heusler alloy.

Non-patent Literature (NPL) 1 discloses the cases of evaporating various buffer layers (Mo, Ti, and the like) onto lithium niobate (LiNbO₃) substrates, as a piezoelectric material, and then epitaxially growing TbFe₂, which is a ferromagnetostrictive material, on the buffer layers. The LiNbO₃ substrates are cleaned before use and evacuated at 500° C. When Ti is used as a buffer layer, the Ti layer is disclosed to be deposited at 100° C. When Mo is used as a buffer layer, the Mo layer is disclosed to be deposited at 450° C. The TbFe₂ layer is deposited on the buffer layer at 650° C.

NPL 2 discloses the case of nonvolatile and repeatable magnetization vector switching in a residual magnetization state using in-plane uniaxial magnetic anisotropy of a polycrystalline Co₂FeSi film, which is a Heusler alloy, grown on a single crystal PMN-PT(011) substrate. Note that, the PMN-PT is an abbreviation for Pb(Mg_{1/3}Nb_{2/3})O₃-PbTiO₃. The Co₂FeSi film is disclosed to be grown to a thickness of 30 nm using molecular beam epitaxy (MBE). An Fe layer with a thickness of 0.3 nm is disclosed to be disposed between the Co₂FeSi film and the PMN-PT substrate. It is described that the Fe layer improves the crystallinity of the Co₂FeSi film, and the disposition of the Fe layer with a thickness of 0.3 nm is essential to improve the crystallinity of the Co₂FeSi film with the L2₁ structure. In contrast, it is described that when no Fe layer is used, a polycrystalline Co₂FeSi film that is grown directly on a PMN-PT substrate is completely non-oriented. The Co₂FeSi film and the Fe layer are disclosed to be deposited at a growth temperature of 300° C. It is seen from an observation result using high-resolution transmission electron microscopy, an amorphous layer is formed between the PMN-PT substrate and the Co₂FeSi film. It is indicated from observation of an EDX spectrum that the amorphous layer is an oxide with little Co, Fe, or Si. Note that, this EDX spectrum is not disclosed in NPL 2.

NPL 3 discloses a case in which annealing treatment was performed on samples, in which Fe thin films were evaporated onto LiNbO₃ substrates, being a ferroelectric material, by vapor phase epitaxy, and the changes in the surface structure and magnetic properties of the Fe thin films with respect to annealing temperature were investigated. NPL 3 indicates that the interface structure between the Fe thin film and the lithium niobate substrate is disordered as annealing temperature increases.

NPL 4 discloses a method of measuring the damping constant.

### CITATION LIST

### Patent Literature

PTL 1: WO 2012/121230 A1

PTL 2: WO 2007/126071 A1

### Non-Patent Literature

NPL 1: Epitaxial growth of TbFe₂ on piezoelectric LiNbO₃ Z-cut, Vincent Polewczyk et al., 2020 J. Phys.: Condens. Matter 32 235803

NPL 2: Giant converse magnetoelectric effect in a multiferroic heterostructure with polycrystalline Co₂FeSi, NPG Asia Materials. 43. ISSN 1884-4049

NPL 3: Thermal assisted tailoring of magnetic coercivity in Iron thin films on unstable Lithium Niobate substrate, Journal of Magnetism and Magnetic Materials, Volume 515, 1 Dec. 2020, 167257

NPL 4: Temperature dependence of the effective Gilbert damping constant of FeRh thin films, T. Usami et al., AIP Advances 11, 045302(2021 )

### SUMMARY

### Technical Problem

In a multilayer body or multilayer structure in which a layer (hereinafter referred to as a magnetic layer) of a magnetic material is formed on or above a layer (hereinafter referred to as a piezoelectric layer) of a material that generates vibration, such as a piezoelectric material, it is considered that, for example, injecting vibration into the magnetic material with high efficiency can generate spin currents in the magnetic material with high efficiency. However, when such a multilayer body or the like is formed, the interface between the layers may be disordered due to diffusion of elements in each layer under the influence of heat, for example, and vibration may not be transmitted from the piezoelectric layer to the magnetic layer with high efficiency. For example, a diffusion layer in which elements from one layer diffuse into the other layer or an disordered layer with an disordered structure may be formed between the piezoelectric layer and the magnetic layer, which prevents efficient propagation of vibration from the piezoelectric layer to the magnetic layer. Therefore, it is desirable to suppress disorder at the interface between the piezoelectric layer and the magnetic layer.

In addition, when disorder occurs at the interface, spin currents may be easily attenuated in the magnetic layer. In particular, it is desired for elements that utilize spin currents to generate the spin currents with high efficiency and suppress attenuation of the spin currents.

The present disclosure has been made in light of these circumstances, and aims to provide a multilayer body with suppressed disorder at an interface between a piezoelectric layer and a magnetic layer, an element including the multilayer body, and a method of producing the multilayer body.

### Solution to Problem

A multilayer body according to the present disclosure to achieve the above object includes:
a piezoelectric layer made of a crystal of an oxide having piezoelectricity;
a metal layer; and
a magnetic layer made of a crystal of a Heusler alloy that is a ferromagnetic material,
wherein the piezoelectric layer, the metal layer, and the magnetic layer are stacked in this order.

An element according to the present disclosure to achieve the above object includes:
a piezoelectric layer made of a crystal of an oxide having piezoelectricity;
a metal layer; and
a magnetic layer made of a crystal of a Heusler alloy that is a ferromagnetic material,
wherein
the piezoelectric layer, the metal layer, and the magnetic layer are stacked in this order,
the metal layer has
   a thickness of 10 nm or more and 40 nm or less, and
   an average content of oxygen of 5 at % or less, and
the piezoelectric layer has an average content of a metal element constituting the metal layer of 5 at % or less, within a range of 10 nm from an interface with the metal layer.

A method of producing a multilayer body according to the present disclosure to achieve the above object includes:
a metal layer formation process in which a metal layer is formed on or above a piezoelectric layer made of a crystal of an oxide having piezoelectricity; and
a magnetic layer formation process in which a magnetic layer made of a crystal of a Heusler alloy that is a ferromagnetic material is formed on or above the metal layer,
wherein in the magnetic layer formation process,
   by molecular beam epitaxy,
   the magnetic layer is formed at a growth temperature of 80° C. or more and 450° C. or less.

### Advantageous Effect

According to the present disclosure, it is possible to provide a multilayer body with suppressed disorder at an interface between a piezoelectric layer and a magnetic layer, an element including the multilayer body, and a method of producing the multilayer body.

### BRIEF DESCRIPTION OF THE DRAWINGS

In the accompanying drawings:

FIG. 1 is a schematic diagram of the structure of a multilayer body according to this embodiment when viewed laterally;

FIG. 2 is a schematic diagram of the structure of an element according to this embodiment when viewed laterally;

FIG. 3 is a schematic diagram of the structure of the element according to this embodiment when viewed from above;

FIG. 4 is an explanatory diagram of a metal layer formation process;

FIG. 5 is an explanatory diagram of an etching process;

FIG. 6 is an explanatory diagram of an insulating layer formation process;

FIG. 7 is a TEM image of a cross section of a multilayer body according to Example 1;

FIG. 8 is a TEM image of an area subjected to EDX surface analysis in Example 1;

FIG. 9 is a concentration distribution diagram of Nb in the multilayer body according to Example 1;

FIG. 10 is a concentration distribution diagram of Cr in the multilayer body according to Example 1;

FIG. 11 is a concentration distribution diagram of Si in the multilayer body according to Example 1;

FIG. 12 is a concentration distribution diagram of Fe in the multilayer body according to Example 1;

FIG. 13 is a concentration distribution diagram of Co in the multilayer body according to Example 1;

FIG. 14 is a diagram illustrating position and a scan direction in EDX line analysis of the multilayer body according to Example 1;

FIG. 15 is a graph illustrating the relationship between element concentration and scan distance in the EDX line analysis of the multilayer body according to Example 1;

FIG. 16 is a TEM image of a cross section of a multilayer body according to Comparative Example 1;

FIG. 17 is a TEM image of an area subjected to EDX surface analysis in Comparative Example 1;

FIG. 18 is a concentration distribution diagram of Nb in the multilayer body according to Comparative Example 1;

FIG. 19 is a concentration distribution diagram of V in the multilayer body according to Comparative Example 1;

FIG. 20 is a concentration distribution diagram of Si in the multilayer body according to Comparative Example 1;

FIG. 21 is a concentration distribution diagram of Fe in the multilayer body according to Comparative Example 1;

FIG. 22 is a concentration distribution diagram of Co in the multilayer body according to Comparative Example 1;

FIG. 23 is a diagram illustrating position and a scan direction in EDX line analysis of the multilayer body according to Comparative Example 1;

FIG. 24 is a graph illustrating the relationship between element concentration and scan distance in the EDX line analysis of the multilayer body according to Comparative Example 1;

FIG. 25 is an explanatory diagram of the structure of an element used in Example 2; and

FIG. 26 is a graph of the damping constant measured in Example 2 against electric field intensity.

### DETAILED DESCRIPTION

A multilayer body, an element, and a method of producing the multilayer body according to an embodiment of the present disclosure will be described with reference to the drawings.

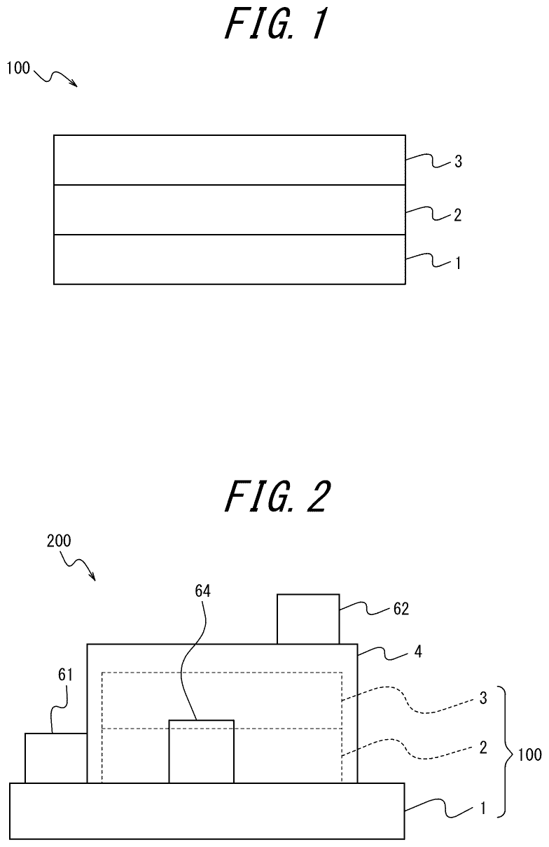

FIG. 1 illustrates a schematic diagram of the structure of a multilayer body 100 according to this embodiment.

The multilayer body 100 includes a piezoelectric layer 1 made of a crystal of an oxide having piezoelectricity, a metal layer 2, and a magnetic layer 3 made of a crystal of a Heusler alloy, which is a ferromagnetic material. In the multilayer body 100, the piezoelectric layer 1, the metal layer 2, and the magnetic layer 3 are stacked in this order.

This multilayer body 100 can be produced, as an example, by a production method that includes a metal layer formation process for forming the metal layer 2 on or above the piezoelectric layer 1, and a magnetic layer formation process for forming the magnetic layer 3 made of a crystal of a Heusler alloy, which is a ferromagnetic material, on or above the metal layer 2, and that forms the magnetic layer 3 in the magnetic layer formation process by molecular beam epitaxy at a growth temperature of 80° C. or more and 450° C. or less.

This multilayer body 100 has suppressed disorder at the interface between the piezoelectric layer 1 and the magnetic layer 3.

The multilayer body 100 can be formed into an element 200 that has the function of e.g., a transistor or the like, by forming into a predetermined structure by etching or the like to form an electrode layer 61 and the like.

The multilayer body 100, the element 200, and the production method thereof according to the present embodiment will be described below in detail.

As described above, the multilayer body 100 is a structure having a stacked structure in which the piezoelectric layer 1, the metal layer 2, and the magnetic layer 3 are stacked in this order. FIG. 1 illustrates a schematic diagram of the structure of the multilayer body 100, viewed from a direction (i.e., laterally) intersecting the direction in which the layers of the multilayer body 100 are stacked. In the multilayer body 100, vibration generated by applying a voltage (electric field) to the piezoelectric layer 1 propagates from the piezoelectric layer 1 to the magnetic layer 3, and a spin wave can be generated in the magnetic layer 3.

The piezoelectric layer 1 is a substrate on or above which the metal layer 2 and the magnetic layer 3 are formed. The piezoelectric layer 1 is a vibration generation source to generate vibration, specifically, a surface acoustic wave to be injected into the magnetic layer 3. The piezoelectric layer 1 has a thickness of, for example, 200 nm or more and 500 μm or less.

The piezoelectric layer 1 is formed of a crystal of an oxide having piezoelectricity. The piezoelectric layer 1 can generate vibration by being applied with a voltage.

The piezoelectric layer 1 is preferably a single crystal. When the piezoelectric layer 1 is a single crystal, the regularity of crystals of the metal layer 2 and the magnetic layer 3 formed on or above the piezoelectric layer 1 is improved. When the piezoelectric layer 1 is a single crystal, the metal layer 2 and the magnetic layer 3 can be grown as single crystals. This allows vibration to propagate from the piezoelectric layer 1 to the magnetic layer 3 via the metal layer 2 with high efficiency, and allows a spin wave to be generated in the magnetic layer 3 with high efficiency. This can also suppress attenuation of the spin wave in the magnetic layer 3.

The oxide that forms the piezoelectric layer 1 is preferably a dielectric material, for example.

The oxide that forms the piezoelectric layer 1 preferably has a mechanical quality factor of 100 or more, and more preferably has a mechanical quality factor of 1000 or more. The mechanical quality factor is a constant that represents the sharpness of mechanical vibration at the vicinity of a resonance frequency, and the larger the value, the sharper. The larger the mechanical quality factor of the oxide that forms the piezoelectric layer 1, the more efficiently the vibration can propagate from the piezoelectric layer 1 to the magnetic layer 3 via the metal layer 2, and the more efficiently the spin wave can be generated in the magnetic layer 3.

An example of the oxide suitable as the piezoelectric layer 1 is preferably a compound represented by a chemical formula ABO₃. That is, the piezoelectric layer 1 may contain a compound that can be represented by the chemical formula ABO₃ as an oxide, and the piezoelectric layer 1 may be made of a compound that can be represented by the chemical formula ABO₃ as an oxide. Here, in the chemical formula ABO₃, A is a metal element, and B is one or more metal elements different from A. Note that, the oxide represented by the chemical formula ABO₃ includes compounds in which B includes B′ and B″ (where B″ is a metal element different from B′) and that can be represented as AB′×B″₁₋ₓO₃ (where 0<x<1).

An example of the oxide suitable as the piezoelectric layer 1 is silicon dioxide (quartz crystal, SiO₂), lithium niobate (LiNbO₃), or lithium tantalate (LiTaO₃). That is, the piezoelectric layer 1 may contain, as an oxide, one or more selected from the group consisting of silicon dioxide, lithium niobate, and lithium tantalate. A particularly suitable oxide, as the piezoelectric layer 1, is an oxide having an ilmenite structure, such as lithium niobate and lithium tantalate, which have compositions corresponding to the chemical formulae ABO₃. When a lithium niobate substrate is used as the piezoelectric layer 1, the lithium niobate substrate may be Z-cut or Y-cut.

In the piezoelectric layer 1, the average content of a metal element constituting the metal layer 2 within a range of 10 nm from the interface with the metal layer 2, which is described later, is preferably 5 at % (atom %: atomic compositional percentage) or less. This may suppress disorder at the interface between the piezoelectric layer 1 and the metal layer 2, and smooth the interface. By suppressing disorder at the interface between the piezoelectric layer 1 and the metal layer 2, vibration can propagate from the piezoelectric layer 1 to the magnetic layer 3 via the metal layer 2 with high efficiency, and a spin wave can be generated in the magnetic layer 3 with high efficiency. It is also possible to suppress attenuation of the spin wave in the magnetic layer 3.

The metal layer 2 is a layer of a metal disposed between the piezoelectric layer 1 and the magnetic layer 3. The metal layer 2 functions as a buffer layer that suppresses diffusion of mutual elements between the piezoelectric layer 1 and the magnetic layer 3. The metal layer 2 is also an underlayer for forming the magnetic layer 3 above the piezoelectric layer 1.

The metal layer 2 is preferably a single crystal. When the metal layer 2 is a single crystal, the regularity of a crystal of the magnetic layer 3 formed on or above the metal layer 2 is improved. When the metal layer 2 is a single crystal, the magnetic layer 3 can be grown as a single crystal. This allows vibration to propagate from the piezoelectric layer 1 to the magnetic layer 3 via the metal layer 2 with high efficiency, and allows a spin wave to be generated in the magnetic layer 3 with high efficiency. This can also suppress attenuation of the spin wave in the magnetic layer 3.

The disposition of the metal layer 2 between the piezoelectric layer 1 and the magnetic layer 3 suppresses diffusion of mutual elements between the piezoelectric layer 1 and the magnetic layer 3. Suppressing this diffusion suppresses disorder at the interface between the piezoelectric layer 1 and the magnetic layer 3.

The disposition of the metal layer 2 on or above the piezoelectric layer 1 and the formation of the magnetic layer 3 on or above the metal layer 2 improve the regularity of the crystal of the magnetic layer 3, as described later. This allows vibration to propagate from the piezoelectric layer 1 to the magnetic layer 3 via the metal layer 2 with high efficiency, and allows a spin wave to be generated in the magnetic layer 3 with high efficiency. This can also suppress attenuation of the spin wave in the magnetic layer 3.

Note that, with respect to propagating vibration to the magnetic layer 3 and generating a spin wave in the magnetic layer 3, “high efficiency” means the energy of the vibration that is converted into heat is small when the energy of the vibration is converted into the spin wave.

The metal layer 2 preferably includes a layer of a metal of a cubic system or hexagonal system at room temperature, with a thickness of 3 nm or more, more preferably a thickness of 10 nm or more, and more preferably includes a layer of a metal that is a body-centered cubic crystal. This improves the regularity of the crystal of the magnetic layer 3, which may result in improvement in the propagation efficiency of vibration from the piezoelectric layer 1 to the magnetic layer 3, improvement in the generation efficiency of a spin wave in the magnetic layer 3, and suppression of attenuation of the spin wave in the magnetic layer 3. The metal layer 2 may be formed of a layer of a metal that is a body-centered cubic crystal at room temperature.

The metal layer 2 is preferably a layer with a thickness of 3 nm or more, and more preferably a thickness of 10 nm or more. The thickness of the metal layer 2 is preferably 40 nm or less. Setting the metal layer 2 as a layer with a thickness of 3 nm or more improves the regularity of the crystal of the magnetic layer 3, which may result in improvement in the propagation efficiency of vibration from the piezoelectric layer 1 to the magnetic layer 3, improvement in the generation efficiency of a spin wave in the magnetic layer 3, and suppression of attenuation of the spin wave in the magnetic layer 3.

Note that, setting the thickness of the metal layer 2 exceeding 40 nm, vibration propagating from the piezoelectric layer 1 to the magnetic layer 3 may be attenuated, or a spin wave may be easily attenuated in the magnetic layer 3. When the thickness of the metal layer 2 is thinner as appropriate, the generation efficiency of a spin wave in the magnetic layer 3 is improved.

The layer of a metal included in the metal layer 2 is preferably made of at least one metal selected from the group consisting of iron (Fe), chromium (Cr), and vanadium (V). This improves the regularity of the crystal of the magnetic layer 3, which may result in improvement in the propagation efficiency of vibration from the piezoelectric layer 1 to the magnetic layer 3, improvement in the generation efficiency of a spin wave in the magnetic layer 3, and suppression of attenuation of the spin wave in the magnetic layer 3. The metal layer 2 may be formed of a layer of a metal that is a body-centered cubic crystal at room temperature. The metal layer 2 may be a layer of these metals. Iron (Fe), chromium (Cr), and vanadium (V) are metals that are body-centered cubic crystals at room temperature, and are suitable as metals that form the metal layer 2.

The metal layer 2 preferably has an average content of oxygen of 5 at % or less. This suppresses disorder at the interface between the metal layer 2 and the magnetic layer 3, which allows vibration to propagate from the piezoelectric layer 1 to the magnetic layer 3 via the metal layer 2 with high efficiency, and allows a spin wave to be generated in the magnetic layer 3 with high efficiency. This can also suppress attenuation of the spin wave in the magnetic layer 3.

The magnetic layer 3 is a layer made of a crystal of a Heusler alloy, which is a ferromagnetic material. In the magnetic layer 3, vibration generated in the piezoelectric layer 1 is converted into a spin wave. The magnetic layer 3 also functions as a medium that propagates the generated spin wave. The magnetic layers 3 has a thickness of 5 nm or more and 100 nm or less, for example.

The Heusler alloy that forms the magnetic layer 3 can be represented by a chemical formula X₂YZ, and the crystalline structure of the alloy is preferably the L2₁ structure. Therefore, vibration from the piezoelectric layer 1 can be converted into a spin wave with high efficiency. Note that, in the chemical formula X₂YZ, X and Y are the same or different elements, and Z is an element different from X and Y.

Note that, the Heusler alloy represented by the chemical formula X₂YZ, as described above, includes alloys in which Y includes Y′ and Y″ (where Y″ is an element different from Y′) and that can be represented as X₂Y′ₓY″₁₋ₓZ (where 0<x<1). The Heusler alloy represented by the chemical formula X₂YZ, as described above, also includes alloys in which Z includes Z′ and Z″ (where Z″ is an element different from Z′) and that can be represented as X₂YZ′ₓZ″₁₋ₓ (where 0<x<1). In the following description, alloys that can be represented as X₂Y′ₓY″₁₋ₓZ are referred to as X₂(Y′, Y″)Z, and alloys that can be represented to as X₂YZ′ₓZ″₁₋ₓ are referred to as X₂Y(Z′, Z″).

An example of the alloy suitable as the Heusler alloy that forms the magnetic layer 3 is an alloy that can be represented by the chemical formula X₂YZ and that has the L2₁ crystalline structure and half-metal properties (i.e., high spin polarization). Specific examples of such an alloy include Co₂FeSi, Co₂FeAl, Co₂Fe(Si, Al), Co₂FeGa, Co₂MnSi, Co₂MnGe, Co₂MnSn, Co₂(Fe, Mn)Si, Co₂MnGa, Fe₃Si. Note that, Fe₃Si corresponds to Fe₂FeSi when expressed in accordance with the notation of the chemical formula X₂YZ. When the Heusler alloy that forms the magnetic layer 3 is these alloys, the propagation efficiency of a spin wave through the magnetic layer 3 becomes high, and long-distance propagation of the spin wave becomes possible. This high propagation efficiency of the spin wave is particularly important when the multilayer body 100 is used as the element 200.

The magnetic layer 3 preferably has a magnetization of 600 emu/cm³ or more. This allows vibration from the piezoelectric layer 1 to be converted into a spin wave with high efficiency. As the magnetization, a value measured by a commercially available vibrating sample type magnetometer may be adopted. The magnetization is a value at 25° C.

Note that, the magnetic layer 3 has a damping constant (magnetic friction coefficient) of 1.0×10⁻² or less, preferably has a damping constant of 5.0×10⁻³ or less. This increases the propagation efficiency of a spin wave through the magnetic layer 3, and allows long-distance propagation of the spin wave. As the damping constant, a value calculated from the linewidth of a ferromagnetic resonance spectrum may be used. This damping constant is a value at 25° C.

Note that, when an alternating current magnetic field with an angular frequency ω is applied to a plane (xy plane) perpendicular to the direction (z-axis direction) of an effective magnetic field, the magnetization receives a torque from the alternating current magnetic field and precesses at the angular frequency ω around the z-axis. Ferromagnetic resonance (hereinafter also referred to as “FMR”) refers to a resonance phenomenon in which the precession is strongly excited when the frequency f (=ω/2π) of the alternating current magnetic field coincides with the Larmor frequency of the magnetization.

The damping constant may be calculated as follows according to the disclosure of NPL 4. A sample is set on an antenna using a coplanar waveguide (hereinafter also referred to as “CPW”), and the S₂₁ parameter is measured by a vector network analyzer (hereinafter also referred to as “VNA”) while sweeping the frequency of a microwave signal transmitted through the antenna. FMR spectra of a resonance frequency fᵣₑₛ and a half-width ΔH are obtained while varying the magnitude of an external static magnetic field H. The half-width AH is plotted against the resonant frequency fᵣₑₛ, and the damping constant is calculated from the slope.

The magnetic layer 3 is preferably a single crystal. When the magnetic layer 3 is a single crystal, the generation efficiency and propagation speed of a spin wave in the magnetic layer 3 are greatly improved. The crystallinity of the Heusler alloy as the magnetic layer 3 affects the value of the damping constant, and the damping constant becomes low when the crystallinity is high. This is preferable because the performance of the element 200 can be increased when the multilayer body 100 is used as the element 200.

Note that, in the multilayer body 100, it is preferable that the elements at each of the interfaces of the piezoelectric layer 1, the metal layer 2, and the magnetic layer 3 are mutually diffused to be 10 nm or less, preferably 5 nm or less, and each layer is epitaxially bonded.

In the multilayer body 100, it is preferable to match the acoustic impedance of the respective layers of the piezoelectric layer 1, the metal layer 2, and the magnetic layer 3. The term “match the acoustic impedance of the respective layers” means that the multilayer body 100 is designed so that the values of the acoustic impedance of the respective layers are close to each other. By the acoustic impedance matching of the respective layers of the multilayer body 100, energy loss during the propagation of vibration (surface acoustic wave) generated in the piezoelectric layer 1 to the magnetic layer 3 is reduced, and the generation efficiency of a spin wave in the magnetic layer 3 can be thereby increased.

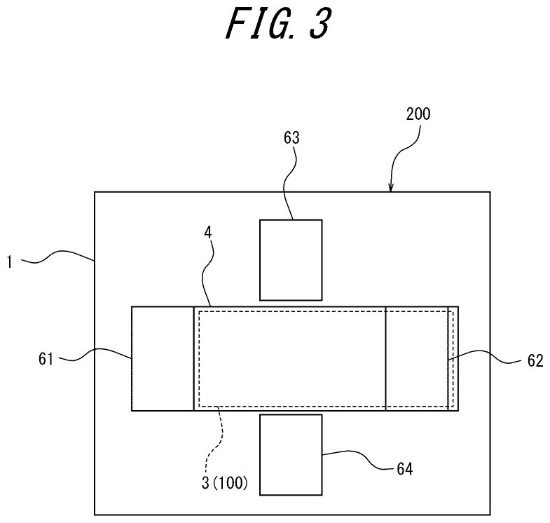

FIG. 2 and FIG. 3 illustrate an example of the element 200 including the multilayer body 100. FIG. 2 is a schematic diagram illustrating a stacked structure when the element 200 is viewed from a lateral side (the side of an electrode layer 64, which is described later) of the layers of the multilayer body 100. FIG. 3 is a schematic diagram when the element 200 is viewed from the side of the magnetic layer 3 of the multilayer body 100 (top view). In the following description, the side of the magnetic layer 3 in the multilayer body 100 is referred to as top, an upper side, an upper surface side, or the like, and the opposite direction thereof is referred to as bottom, a lower side, or a lower surface side. For example, in the multilayer body 100, the magnetic layer 3 is a layer disposed on the upper side of the metal layer 2, and the piezoelectric layer 1 is a layer disposed on the lower side of the magnetic layer 3. The direction in which the layers of the multilayer body 100 are stacked is the same as a vertical direction.

As illustrated in FIG. 2, the element 200 includes the multilayer body 100 including the piezoelectric layer 1, the metal layer 2, and the magnetic layer 3, and an insulating layer 4 that covers and insulates the metal layer 2 and the magnetic layer 3. As illustrated in FIG. 3, the element 200 includes electrode layers 61, 62, 63, and 64. In the element 200, in a top view, the magnetic layer 3 and the insulating layer 4 are smaller than the piezoelectric layer 1, and are disposed in a middle portion on a plane surface of the piezoelectric layer 1. Note that, the metal layer 2 (see FIG. 2) overlaps the magnetic layer 3 in the top view, and the metal layer 2 and the magnetic layer 3 have the same shape in the top view. FIG. 2 and FIG. 3 illustrate a case in which the magnetic layer 3 is rectangular in shape.

The insulating layer 4 is a layer to insulate the metal layer 2 and the magnetic layer 3 from the electrode layers 61, 62, 63, and 64, which are illustrated in FIG. 3, and the outside. The insulating layer 4 may be a film made of silicon dioxide (SiO₂), for example.

The electrode layers 61, 62, 63, and 64 are electrodes made of a metal of a conductor such as gold.

The electrode layers 61, 63, and 64 are disposed on the piezoelectric layer 1. The electrode layer 61 is disposed close to the insulating layer 4 to the extent of not contacting the insulating layer 4. As illustrated in FIG. 2, the electrode layer 62 is disposed on an upper surface portion of the insulating layer 4 on the upper surface side of the magnetic layer 3.

The electrode layer 61 is an electrode (source) to apply a voltage (electric field) to the piezoelectric layer 1. The electrode layer 61 is disposed on the piezoelectric layer 1 on the side of one end (first end) of the rectangular magnetic layer 3 in a longitudinal direction. As the electrode layer 61, for example, a interdigitated array (comb-shaped) electrode formed of a Ti/Au bilayer film may be used.

The electrode layer 62 is an electrode (drain) to detect a spin wave propagating through the magnetic layer 3. The electrode layer 62 is disposed at an end (second end) on the other side from the side on which the electrode layer 61 is disposed.

By applying a voltage to the electrode layer 61, an electric field is applied to the piezoelectric layer 1. This enables the piezoelectric layer 1 to generate a surface acoustic wave, in the element 200. The surface acoustic wave generated in the piezoelectric layer 1 propagates from the piezoelectric layer 1 to the magnetic layer 3 via the metal layer 2. The surface acoustic wave generated in the piezoelectric layer 1 propagates through the multilayer body 100 from the side of the electrode layer 61 to the side of the electrode layer 62 along the longitudinal direction of the magnetic layer 3. Due to the propagation of the surface acoustic wave, a spin wave is generated in the magnetic layer 3. The spin wave propagates through the magnetic layer 3 from the side of the electrode layer 61 to the side of the electrode layer 62 along the longitudinal direction of the magnetic layer 3. The spin wave that has propagated through the magnetic layer 3 and has reached the vicinity of the electrode layer 62 can be detected by the electrode layer 62 by an induced electromotive force generated by the spin wave. Since the magnetic layer 3 is made of a Heusler alloy in the present embodiment, the attenuation of the spin wave propagating through the magnetic layer 3 is suppressed well. Therefore, in the element 200, it is possible to achieve reduction in the amount of heat generation, improvement in the degree of freedom in designing the shape, and improvement in the reliability in signal transmission based on the propagation of the spin wave.

The electrode layers 63 and 64 are a pair of electrodes (gate) disposed on the sides of one end (third end) and the other end (fourth end) of the rectangular magnetic layer 3 in a lateral direction. By applying an electric field between the electrode layers 63 and 64, the magnetism of the magnetic layer 3 is controlled.

Specifically, by applying an electric field between the electrode layers 63 and 64, it is possible to amplify or attenuate a spin wave propagating from the side of the electrode layer 61 toward the electrode layer 62 through the magnetic layer 3. In the element 200, by switching between a state (ON) in which an electric field is applied between the electrode layers 63 and 64 and a state (OFF) in which no electric field is applied, the intensity of a spin wave detected by the electrode layer 62 can be increased or decreased, and a signal can be transmitted with the magnitude of the intensity. Thus, the element 200 can realize the function of a transistor. As described above, in the element 200, the function of a transistor can be realized without generating Joule's heat due to energization.

Note that, the reason why the intensity of a spin wave detected by the electrode layer 62 can be increased or decreased by switching between a state (ON) in which an electric field is applied between the electrode layers 63 and 64 and a state (OFF) in which no electric field is applied, as described above, is that, for example, the damping constant of the magnetic layer 3 can be modulated by switching the state of the electric field.

Note that, the multilayer body 100 may have a structure other than the structure of the element 200 illustrated above. The multilayer body 100 is not limited to being used as an element having the function of a transistor, such as the element 200 illustrated above, and may be used as other elements such as an amplifier element and a magnetic switching element. Also, it is not excluded to use as a magnetic device other than these.

The multilayer body 100 and the element 200 including this can be produced as follows.

As described above, the multilayer body 100 can be produced by a production method that includes a metal layer formation process for forming the metal layer 2 on or above the piezoelectric layer 1, and a magnetic layer formation process for forming the magnetic layer 3 on or above the metal layer 2.

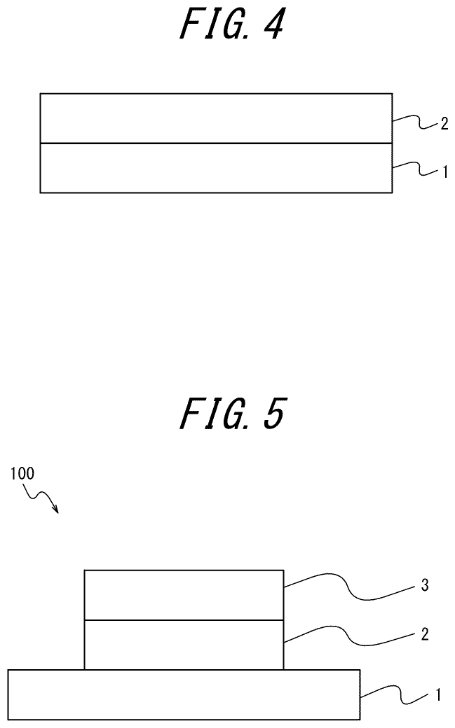

In the metal layer formation process, as illustrated in FIG. 4, the metal layer 2 may be formed by, for example, molecular beam epitaxy (MBE) on the piezoelectric layer 1 formed to a predetermined thickness in advance. Note that, as the piezoelectric layer 1, one with a smooth surface may be used. As the piezoelectric layer 1, one of a single crystal is preferably used. The metal layer 2 may be formed with a smooth surface. The surface of the piezoelectric layer 1 and the surface of the metal layer 2 each preferably have a root mean square surface roughness of 1 nm or less.

In the metal layer formation process, the metal layer 2 may be formed by molecular beam epitaxy at a growth temperature of 80° C. or more and 450° C. or less. The growth temperature is preferably 200° C. or more and 400° C. or less.

By setting the growth temperature in the metal layer formation process to the temperature as described above, it is possible to suppress the diffusion of elements between the metal layer 2 and the piezoelectric layer 1. This can suppress disorder at the interface between the metal layer 2 and the piezoelectric layer 1. The molecular beam epitaxy is suitable for forming the metal layer 2 at a low temperature, such as the above growth temperature.

Setting the growth temperature in the metal layer formation process to the above temperature can suppress the growth of the metal layer 2 in the shape of islands, and suppress deterioration in the flatness of the surface of the metal layer 2. Suppressing deterioration in the flatness of the surface of the metal layer 2 can prevent reduction in the regularity of the crystal of the magnetic layer 3 formed on the metal layer 2 and the like, and suppress reduction in the generation efficiency of a spin wave in the magnetic layer 3 and the attenuation of the spin wave during propagation of the spin wave through the magnetic layer 3 (for example, prevent increase in the damping constant).

By setting the growth temperature in the metal layer formation process to the above temperature, it is possible to prevent deterioration in the piezoelectric layer 1, that is, deterioration in characteristics as a piezoelectric body by changing the composition of the piezoelectric layer 1 due to the diffusion of elements from the piezoelectric layer 1 to the metal layer 2 or the diffusion of element from the metal layer 2 to the piezoelectric layer 1.

The magnetic layer formation process is performed after the metal layer formation process. In the magnetic layer formation process, the magnetic layer 3 is formed on or above the metal layer 2 by molecular beam epitaxy. This results in the obtainment of the multilayer body 100 as illustrated in FIG. 1.

In the magnetic layer formation process, the magnetic layer 3 is formed at a growth temperature of 80° C. or more and 450° C. or less. The growth temperature is preferably 200° C. or more and 400° C. or less. In the magnetic layer formation process, heat treatment to improve the regularity of the crystal of the magnetic layer 3 is allowed within a range in which each of the interfaces between the piezoelectric layer 1, the metal layer 2, and the magnetic layer 3 is not disordered.

Note that, in the magnetic layer formation process, it is possible to crystallize the Heusler alloy even when the magnetic layer 3 is formed at a temperature lower than the growth temperature described above. However, when the heat treatment is required to promote crystal ordering of the Heusler alloy in the magnetic layer 3 that has been once crystallized at a low temperature (including the case of having crystallized to the B2 structure, the case of having crystallized to the A2 structure that is not ordered, and the case of having polycrystallized), the effect of the crystal ordering promotion may not be obtained unless the heat treatment is not performed at a high temperature to some extent (e.g., a temperature exceeding 200° C.). In such a case, the Heusler alloy layer of the L2₁ structure may be formed more easily in the magnetic layer 3 by forming the magnetic layer 3 with a growth temperature in the temperature range described above, than by attempting the heat treatment.

By setting the growth temperature in the magnetic layer formation process to the above temperature, it is possible to suppress the diffusion of elements between the metal layer 2 and the piezoelectric layer 1. This can suppress disorder at the interface between the metal layer 2 and the piezoelectric layer 1. The molecular beam epitaxy is suitable for forming the magnetic layer 3 at a low temperature, such as the above growth temperature.

By setting the growth temperature in the magnetic layer formation process to the above temperature, it is possible to prevent deterioration in the piezoelectric layer 1, that is, deterioration in characteristics as a piezoelectric body by changing the composition of the piezoelectric layer 1 due to the diffusion of elements from the piezoelectric layer 1 to the metal layer 2 or the diffusion of an element from the metal layer 2 to the piezoelectric layer 1.

By setting the growth temperature in the magnetic layer formation process to the temperature as described above, it is possible to suppress the diffusion of elements between the magnetic layer 3 and the metal layer 2. This can suppress disorder at the interface between the magnetic layer 3 and the metal layer 2.

By setting the growth temperature in the magnetic layer formation process to the above temperature, it is possible to prevent deterioration in the magnetic layer 3, that is, deterioration in characteristics as a piezoelectric body by changing the composition of the magnetic layer 3 due to the diffusion of an element from the metal layer 2 to the magnetic layer 3 or the diffusion of elements from the magnetic layer 3 to the metal layer 2.

When the element 200 is produced using the multilayer body 100, the multilayer body 100 is subsequently patterned using a lithography apparatus, and as illustrated in FIG. 5, is subjected to an etching process in which part of the metal layer 2 and part of the magnetic layer 3 are removed using an etching apparatus.

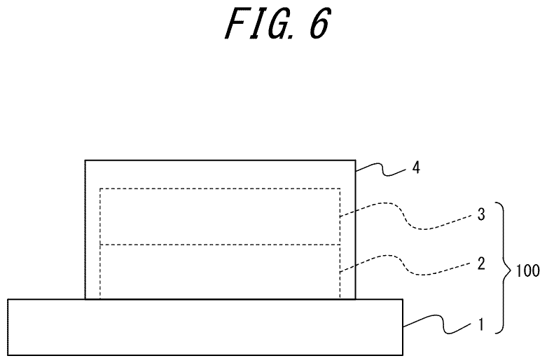

After part of the metal layer 2 and part of the magnetic layer 3 are removed from the multilayer body 100, an insulating layer formation process is performed in which, as illustrated in FIG. 6, the insulating layer 4 made of silicon dioxide or the like is formed on surfaces (surface portions exposed without forming an interface with another layer) of the metal layer 2 and the magnetic layer 3 remaining. The insulating layer 4 may be formed by patterning using the lithography apparatus or the like and deposition (vapor deposition) using a vacuum thin-film apparatus.

Finally, as illustrated in FIG. 2 and FIG. 3, the electrode layers 61, 62, 63, and 64 are formed as electrodes at predetermined positions. These electrodes may be patterned by the lithography apparatus or the like and deposited (vapor deposition) using the vacuum thin-film apparatus.

### EXAMPLES

The multilayer body according to the present embodiment will be further described below based on Examples.

### Example 1

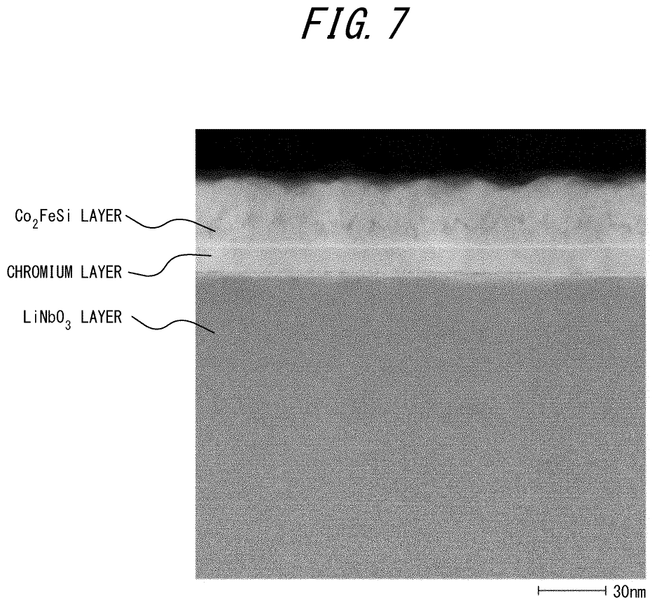

A chromium layer as a metal layer and a Co₂FeSi layer as a magnetic layer were formed on a LiNbO₃ substrate (Y-cut) as a piezoelectric layer, as described later, thereby obtaining a multilayer body according to Example 1. FIG. 7 illustrates a TEM image of a cross section of the multilayer body according to Example 1. In the following description, a TEM image is a high-angle annular dark field scanning TEM (HAADF-STEM) image captured by a JEM-ARM200F manufactured by JEOL Ltd. under the condition of an acceleration voltage of 200 kV.

This multilayer body was produced as follows by forming the metal layer and a ferromagnetic Heusler alloy layer, as the magnetic layer, on the LiNbO₃ substrate in this order using molecular beam epitaxy (MBE).

As the LiNbO₃ substrate, a commercially available LiNbO₃ substrate (128° Y-cut, thickness 0.5 mm, manufactured by Yamaju Ceramics Co., Ltd.) was adopted.

First, the LiNbO₃ substrate was subjected to surface treatment as follows. First, the LiNbO₃ substrate was chemically cleaned. In the chemical cleaning, a surface protective resist that had been applied to a surface of the LiNbO₃ substrate was peeled off using dimethylacetamide, and then the substrate surface was cleaned with isopropanol. The cleaning with isopropanol was performed by rubbing and polishing the substrate surface with a cotton swab while the LiNbO₃ substrate was immersed in isopropanol. In this chemical cleaning, surface observation of the substrate was performed sequentially in the process of cleaning with isopropanol, and an end point of the cleaning was determined. The surface observation of the substrate was performed with an optical microscope after the substrate was dried by blowing with dry nitrogen. The cleaning with isopropanol, drying, and observation with the optical microscope were repeated until particles on the substrate surface could not be observed with the optical microscope, and a state in which the particles on the substrate surface could not be observed with the optical microscope was set as an end point of cleaning.

After the surface treatment of the LiNbO₃ substrate, the LiNbO₃ substrate was immediately attached to a holder and loaded into a loading chamber of an MBE apparatus. After this substrate was moved to a growth chamber of the MBE apparatus, the substrate surface was observed using a reflection high energy electron diffraction (RHEED) apparatus mounted in the growth chamber, and it was confirmed that a desired diffraction pattern was observed. Thereafter, this substrate was subjected to heat treatment to hold for 60 minutes at 500° C. in the growth chamber. At this time, the degree of vacuum in the MBE apparatus was maintained at 1×10⁻⁸ Torr or less.

After the heat treatment of the LiNbO₃ substrate, the substrate surface was observed using the RHEED apparatus, and it was confirmed that the diffraction pattern was observed more clearly than before the heat treatment.

Next, the chromium layer as the metal layer was formed on the LiNbO₃ substrate. With the LiNbO₃ substrate maintained at a temperature of 200° C., chromium was heated and evaporated using a Knudsen cell and supplied to the substrate surface, thereby forming the chromium layer on the LiNbO₃ substrate. The chromium layer was formed while the substrate was rotated.

The chromium layer grew at a growth rate of about 0.05 angstroms/s to 0.2 angstroms/s. The vapor deposition rate of chromium was adjusted using a quartz crystal film thickness gauge mounted in the MBE apparatus.

The thickness of the chromium layer was adjusted by vapor deposition time, and set to 10 nm. The degree of vacuum in the MBE growth chamber was maintained at the lower half of the 10⁻⁹ Torr range.

After the formation of the chromium layer, the substrate surface was observed using the RHEED apparatus, and it was confirmed that a streaky diffraction pattern was observed. That is, the chromium layer was formed as a single crystal.

Next, the Co₂FeSi layer was formed on the chromium layer. While the temperature of the LiNbO₃ substrate (hereinafter, sometimes simply referred to as multilayer substrate), on which the chromium layer was formed, was maintained at 200° C., constituent elements (Co, Fe, and Si) of the Co₂FeSi layer were heated and evaporated using a Knudsen cell, and simultaneously supplied to a surface of the chromium layer of the multilayer substrate, in order to form the Co₂FeSi layer on the chromium layer. The growth rate of the Co₂FeSi layer was about 0.2 angstroms/s to 0.4 angstroms/s. The composition ratio of the Co₂FeSi layer was adjusted by adjusting the vapor deposition rate of each element to a ratio corresponding to the composition ratio. Note that, the vapor deposition rate of each element was measured using a nude ion gauge mounted in the MBE apparatus. The thickness of the Co₂FeSi layer was adjusted by vapor deposition time, and set to 30 nm. The degree of vacuum in the MBE growth chamber at the time of forming the Co₂FeSi layer was maintained at the lower half of the 10⁻⁹ Torr range.

After the Co₂FeSi layer was formed, the surface was observed using the RHEED apparatus, and it was confirmed that a streaky diffraction pattern was observed. That is, the Co₂FeSi layer was formed as a single crystal. When the Co₂FeSi layer was separately imaged and confirmed with a high-resolution HAADF-STEM image, it was confirmed that the crystal of the Co₂FeSi layer had the L2₁ structure.

As described above, the multilayer body according to Example 1 was produced.

As is apparent from a TEM image illustrated in FIG. 7, in this multilayer body, the diffusion of elements between the respective layers of the LiNbO₃ substrate, the chromium layer, and the Co₂FeSi layer is suppressed, the disorder of the interface between the respective layers is suppressed, and the respective interfaces are smooth.

For the Co₂FeSi layer of the multilayer body according to Example 1, an FMR spectrum was measured, and the damping constant (magnitude of magnetic friction) was evaluated based on the result. The damping constant was 3.3×10⁻³ to 6.1×10⁻³. That is, the Co₂FeSi layer of the multilayer body according to Example 1 has small magnetic friction and suppressed attenuation of a spin wave. Therefore, it was evaluated that the multilayer body according to Example 1 is suitable for use as an element such as a transistor.

Note that, in the present embodiment, the following apparatuses and measurement conditions were adopted for the measurement of the FMR spectrum.

As a VNA, Keysight E5071C was used.

As a probe, GGB Industries INC. picoprobe 40A-GSG-200-DS-NM was used.

The intensity of microwaves was set to 5 dBm.

The measurement frequency was set to 1 to 20 GHz (sweep interval 19 MHz).

The external magnetic field intensity was set to 3300 Oe at the maximum.

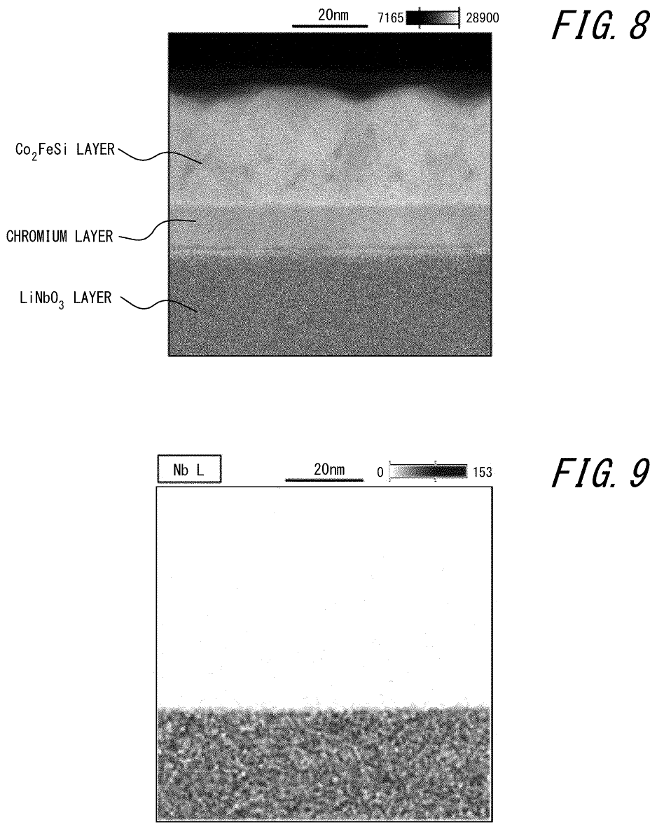

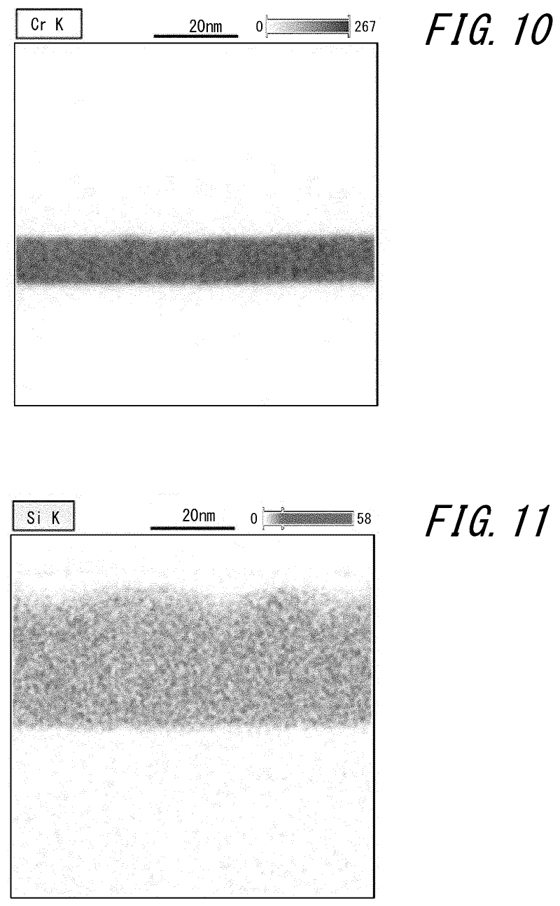

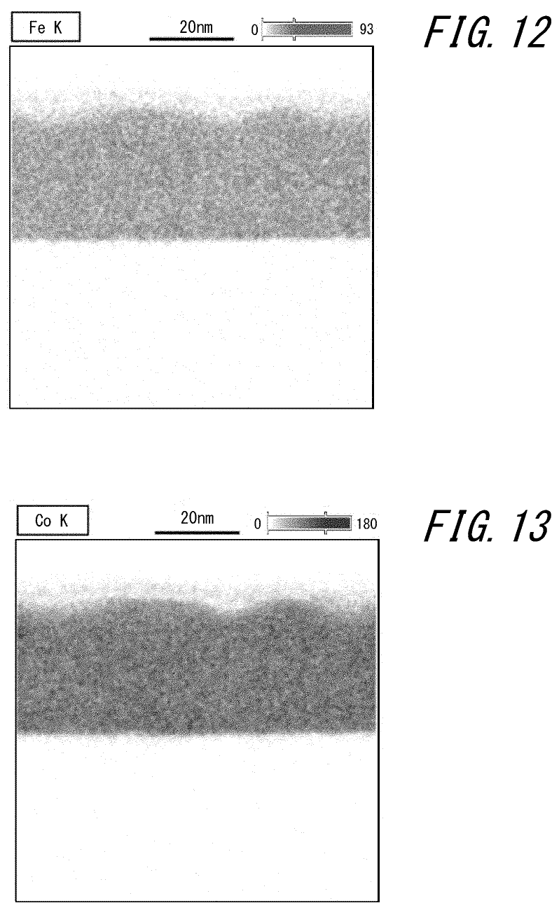

The multilayer body according to Example 1 was further subjected to surface analysis by EDX. FIG. 8 illustrates a TEM image of an area of the multilayer body according to Example 1 subjected to the surface analysis by EDX. FIG. 9 to FIG. 13 illustrate density profiles of Nb (L line), Cr (K line), Si (K line), Fe (K line), and Co (K line) by the surface analysis using EDX in this order. In FIG. 9 to FIG. 13, the magnitude of the concentration of each element is represented by a gray scale, and the closer to black, the higher the concentration of the element to be detected.

It can also be seen from the diagrams illustrated in FIG. 8 to FIG. 13 that, in the multilayer body according to Example 1, elements are suppressed from diffusing between the respective layers of the LiNbO₃ substrate, the chromium layer, and the Co₂FeSi layer.

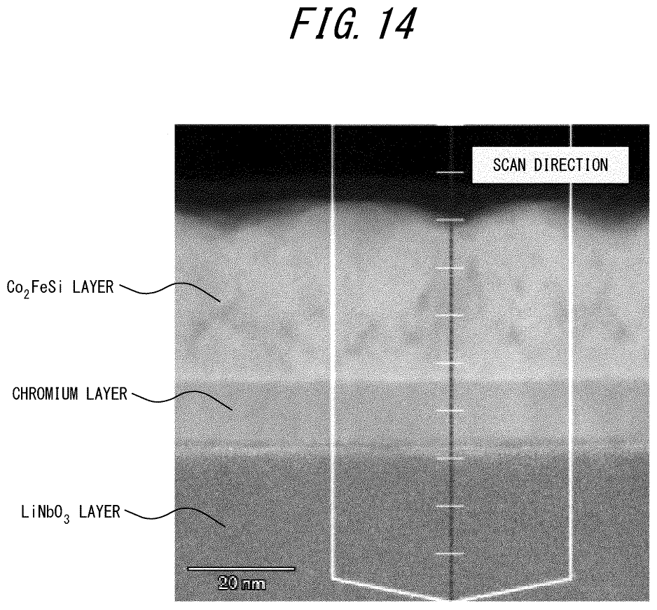

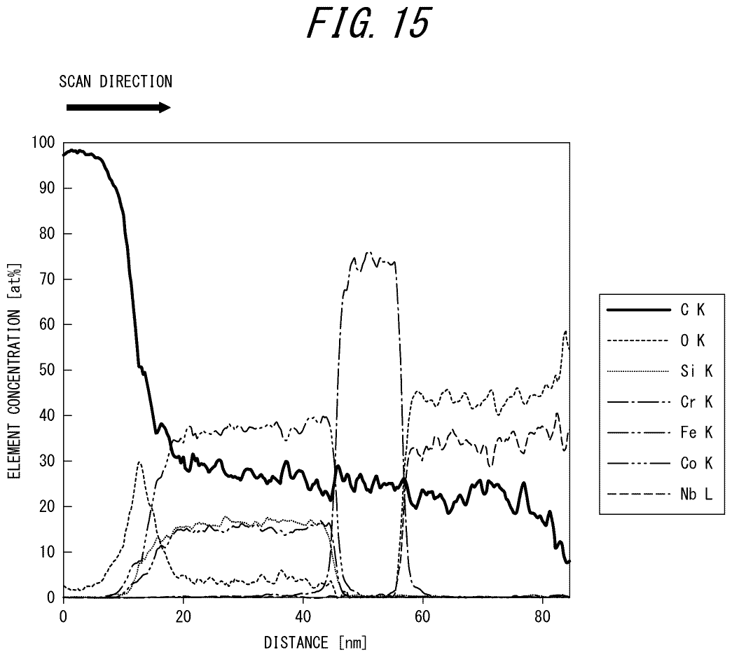

The multilayer body according to Example 1 was further subjected to line analysis by EDX. FIG. 14 illustrates, for a cross section of the multilayer body according to Example 1, position that is subjected to the line analysis by EDX and a scan direction, with being superimposed on the TEM image. FIG. 15 is a graph illustrating the relationship between the element concentration (at %) of C (K line), O (K line), Si (K line), Cr (K line), Fe (K line), Co (K line), and Nb (L line) by the line analysis using EDX and the distance (nm) of scanning along the scan direction. Note that, the orientation and direction of scanning are an orientation perpendicular to the layer structure of the multilayer body, and a direction from the side of the Co₂FeSi layer to the side of the LiNbO₃ layer in the TEM image of FIG. 14. That is, a distance of 0 nm in the graph illustrated in FIG. 15 corresponds to the position of the surface of the Co₂FeSi layer on the side opposite the chromium layer. Although the graph illustrated in FIG. 15 indicates that C (K line) is detected, this is derived from a carbon film that covers the cross section of the multilayer body at the time of TEM observation, and C is not contained in the multilayer body.

It can also be seen from the graph illustrated in FIG. 15 that, in the multilayer body according to Example 1, elements are suppressed from diffusing between the respective layers of the LiNbO₃ substrate, the chromium layer, and the Co₂FeSi layer.

It can be considered from the graph illustrated in FIG. 15 that when the average content of chromium is 5 at % or less within a range of 10 nm from the interface with the chromium layer as the metal layer in the LiNbO₃ substrate as the piezoelectric layer, a state in which disorder is suppressed at the interface between the LiNbO₃ substrate and the chromium layer, as in the TEM image illustrated in FIG. 7 and FIG. 14, can be achieved. Note that, the criterion for the above calculation of the average content of chromium obtained based on the graph illustrated in FIG. 15 does not include the detection amount of carbon (C). The above average content of chromium is a value calculated, based on the graph illustrated in FIG. 15, based on the atomic composition of oxygen (O), silicon (Si), chromium (Cr), iron (Fe), cobalt (Co), and niobium (Nb).

It can also be considered from the graph illustrated in FIG. 15 that when the average content of oxygen is 5 at % or less in the chromium layer as the metal layer, a state in which disorder at the interface between the chromium layer and the Co₂FeSi layer is suppressed can be achieved.

### Comparative Example 1

Next, in contrast to Example 1, a multilayer body according to Comparative Example 1 was obtained by changing the metal layer from the chromium layer with a film thickness of 10 nm to a vanadium layer with a film thickness of 30 nm, and setting the growth temperature of the vanadium layer as a metal layer at 500° C., and setting the other conditions to the same as those in Example 1. In the multilayer body according to Comparative Example 1, a clear streaky diffraction pattern was observed in surface observation using the RHEED apparatus after the formation of the vanadium layer and after the formation of a Co₂FeSi layer. That is, the Co₂FeSi layer was formed as a single crystal.

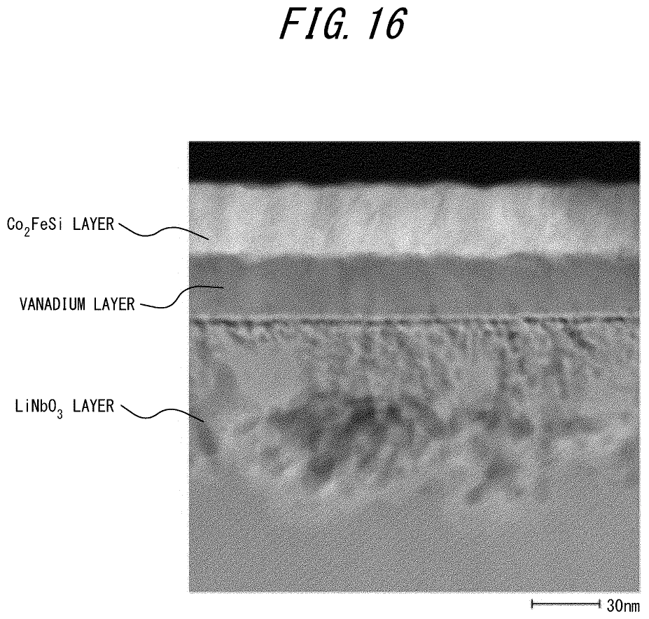

FIG. 16 illustrates a TEM image of a cross section of the multilayer body according to Comparative Example 1. As is apparent from the TEM image illustrated in FIG. 16, in this multilayer body, the interfaces between the respective layers of a LiNbO₃ substrate, the vanadium layer, and the Co₂FeSi layer are disordered, and the unevenness of the respective interfaces is significantly larger than that of the multilayer body according to Example 1. It can also be considered that the disorder of structure that infiltrates from the interface with the vanadium layer into the interior of the LiNbO₃ substrate is caused by significant diffusion of vanadium into the LiNbO₃ substrate.

It can also be considered that disorder at the surface of the vanadium layer on the side of the Co₂FeSi layer or at the interface between the vanadium layer and the Co₂FeSi layer is caused by diffusion of oxygen from the LiNbO₃ substrate into the vanadium layer. This is considered to have induced the disorder at the surface of the vanadium layer on the side of the Co₂FeSi layer or at the interface between the vanadium layer and the Co₂FeSi layer.

For the Co₂FeSi layer of the multilayer body according to Comparative Example 1, a ferromagnetic resonance spectrum was measured, and the damping constant (magnitude of magnetic friction) was evaluated based on the result. The damping constant was 1.4×10⁻² to 1.5×10⁻². That is, the Co₂FeSi layer of the multilayer body according to Comparative Example 1 has significantly larger magnetic friction and more easily attenuates a spin wave than the Co₂FeSi layer of the multilayer body according to Example 1.

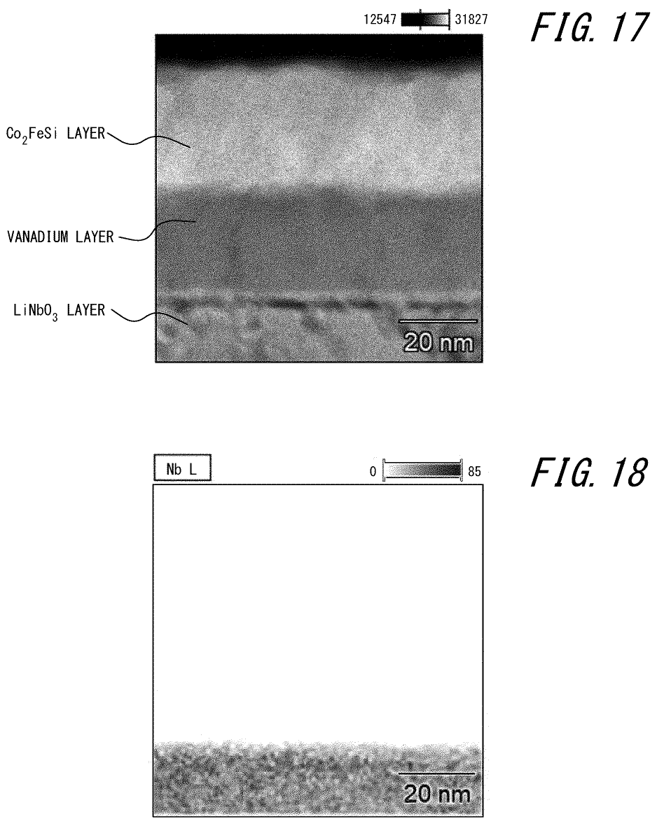

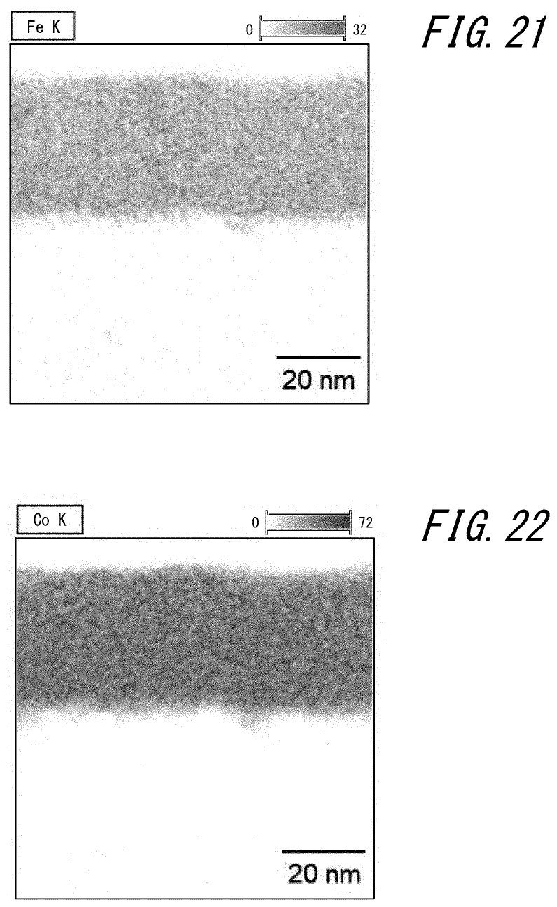

The multilayer body according to Comparative Example 1 was further subjected to surface analysis by EDX. FIG. 17 illustrates a TEM image of an area of the multilayer body according to Comparative Example 1 subjected to the surface analysis by EDX. FIG. 18 to FIG. 22 illustrate density profiles of Nb (L line), V (K line), Si (K line), Fe (K line), and Co (K line) by the surface analysis using EDX in this order. In FIG. 18 to FIG. 22, the magnitude of the concentration of each element is represented by a gray scale, and the closer to black, the higher the concentration of the element to be detected.

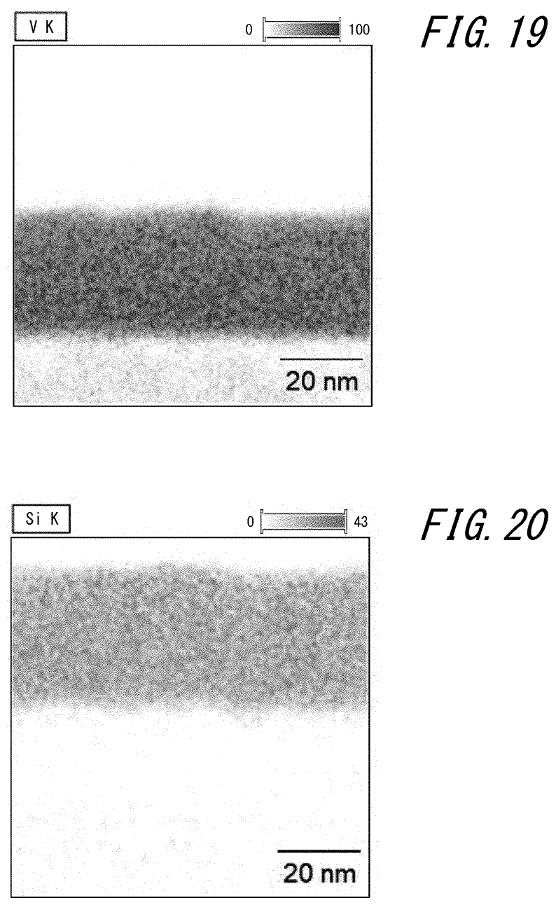

According to the TEM images illustrated in FIG. 16 and FIG. 17, it can be seen that the interfaces between the respective layers of the LiNbO₃ substrate, the vanadium layer, and the Co₂FeSi layer are disordered in the multilayer body according to Comparative Example 1. From FIG. 18 to FIG. 22, significant diffusion of vanadium from the vanadium layer into the LiNbO₃ substrate is observed (see FIG. 19).

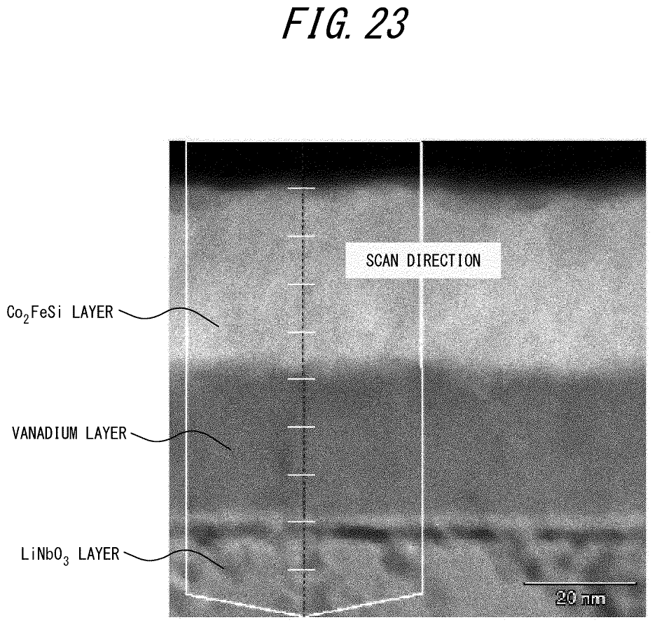

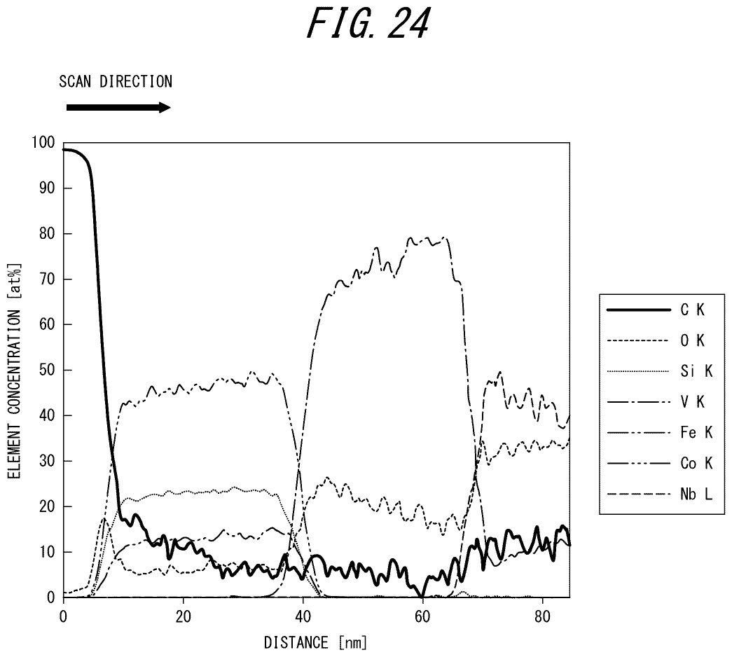

The multilayer body according to Comparative Example 1 was further subjected to line analysis by EDX. FIG. 23 illustrates, for a cross section of the multilayer body according to Comparative Example 1, position that is subjected to the line analysis by EDX and a scan direction, with being superimposed on the TEM image. FIG. 24 is a graph illustrating the relationship between the element concentration (at %) of C (K line), O (K line), Si (K line), V (K line), Fe (K line), Co (K line), and Nb (L line) by the line analysis using EDX and the distance (nm) of scanning along the scan direction. Note that, the orientation and direction of scanning are an orientation perpendicular to the layer structure of the multilayer body, and a direction from the side of the Co₂FeSi layer to the side of the LiNbO₃ layer in the TEM image of FIG. 23. That is, a distance of 0 nm in the graph illustrated in FIG. 24 corresponds to the position of the surface of the Co₂FeSi layer on the side opposite the vanadium layer. Although the graph illustrated in FIG. 24 indicates that C (K line) is detected, this is derived from a carbon film that covers the cross section of the multilayer body at the time of TEM observation, and C is not contained in the multilayer body.

It can also be seen from the graph illustrated in FIG. 24 that, in the multilayer body according to Comparative Example 1, elements significantly diffuse between the LiNbO₃ substrate and the vanadium layer. Specifically, a large amount of vanadium diffuses from the vanadium layer into the LiNbO₃ substrate. In addition, oxygen diffuses into the vanadium layer. It is considered that at least part of the oxygen diffusing into the vanadium layer is supplied from the LiNbO₃ substrate.

It can be considered from the graph illustrated in FIG. 24 that the average content of vanadium exceeds 5 a t% within a range of 10 nm from the interface with the vanadium layer as the metal layer in the LiNbO₃ substrate as the piezoelectric layer, and thus disorder at the interface between the LiNbO₃ substrate and the vanadium layer is promoted, as in the TEM image illustrated in FIG. 16. Note that, the criterion for the above calculation of the average content of vanadium obtained based on the graph illustrated in FIG. 24 does not include the detection amount of carbon (C). The above average content of vanadium is a value calculated, based on the graph illustrated in FIG. 24, based on the atomic composition of oxygen (O), silicon (Si), vanadium (V), iron (Fe), cobalt (Co), and niobium (Nb).

It can be considered from the graph illustrated in FIG. 24 that when the average content of oxygen exceeds 5 at % in the vanadium layer as the metal layer, disorder at the interface between the vanadium layer and the Co₂FeSi layer occurs easily.

### Example 2

It was confirmed using ferromagnetic resonance (FMR) that the propagation of a spin wave through a ferromagnetic Heusler alloy thin film (magnetic layer) can be controlled by an electric field. The control of the propagation of a spin wave was confirmed by confirming whether the damping constant of the multilayer body (magnetic layer) can be controlled by electric field intensity, that is, by measuring variations in the damping constant with respect to electric field intensity.

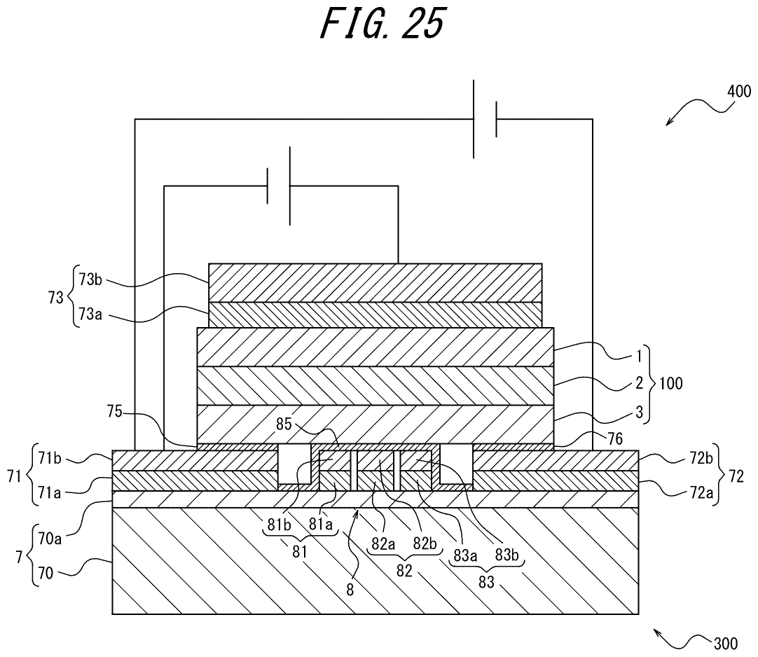

As an element for this measurement, an element 400 having a structure illustrated in FIG. 25 was produced. This element 400 has an antenna substrate 300 in which electrodes 71 and 72 and a coplanar waveguide (CPW) antenna 8 are formed on a surface of an oxide film 70a of a silicon substrate 7 including a silicon layer 70 and the oxide film 70a, which is a silicon oxide film disposed on one surface of the silicon layer 70, the above-described multilayer body 100 disposed on the antenna substrate 300, and an electrode 73 formed on a surface of the multilayer body 100 opposite the antenna substrate 300. The multilayer body 100 is disposed such that the magnetic layer 3 faces the antenna substrate 300.

The multilayer body 100 used in this example was produced in the same manner as the multilayer body produced in Example 1. A piezoelectric layer 1 of the multilayer body 100 in this example was the same as the LiNbO₃ substrate used in Example 1. A metal layer 2 was also a chromium layer having a thickness of 10 nm in the same manner as in Example 1. A magnetic layer 3 was also a Co₂FeSi layer with a thickness of 30 nm in the same manner as in Example 1.

The electrodes 71, 72, and 73 have titanium layers 71a, 72a, and 73a and gold layers 71b, 72b, and 73b. The titanium layers 71a and 72a are formed on the oxide film 70a. The titanium layer 73a is formed on a surface of the piezoelectric layer 1 of the multilayer body 100. The gold layers 71b, 72b, and 73b are formed on surfaces of the titanium layers 71a, 72a, and 73a, respectively. The electrodes 71 and 72 are arranged linearly and in parallel at a predetermined spacing apart.

The CPW antenna 8 includes conductors 81, 82, and 83 that are arranged (wired) on a surface of the oxide film 70a so as to extend linearly and in parallel with spacing from each other. The conductors 81, 82, and 83 have a line width of 100 μm, and the spacing between adjacent lines is 50 μm. The CPW antenna 8 is arranged in parallel with the electrodes 71 and 72. The CPW antenna 8 is disposed between the electrode 71 and the electrode 72, and is spaced apart from the electrodes 71 and 72 by a predetermined distance. Both ends of the CPW antenna 8 are connected with probes to two ports of a VNA. The VNA emits microwaves while sweeping the frequency, to measure a transmission coefficient (S₂₁ parameter).

The conductors 81, 82, and 83 include titanium layers 81a, 82a, and 83a and gold layers 81b, 82b, and 83b. The titanium layers 81a, 82a, and 83a are formed on the surface of the oxide film 70a. The gold layers 81b, 82b, and 83b are formed on surfaces of the titanium layers 81a, 82a, and 83a, respectively.

The electrodes 71 and 72 and the conductors 81, 82, and 83 were formed by evaporating titanium by 5 nm onto the surface of the oxide film 70a using an electron beam evaporation apparatus to stack the titanium layers 71a, 72 a, 81 a, 82a, and 83 a, and then evaporating gold by 300 nm to stack the gold layers 71b, 72b, 81b, 82b, and 83b. The electrode 73 was formed by evaporating titanium by 3 nm onto the surface of the piezoelectric layer 1 using the electron beam evaporation apparatus to stack the titanium layer 73a, and then evaporating gold by 100 nm to stack the gold layer 73b.

An insulating layer 85 made of SiO₂ is formed on the CPW antenna 8 (on the conductors 81, 82, and 83). The insulating layer 85 was formed by depositing SiO₂ by 50 nm using a sputtering apparatus.

Conductive paste layers 75 and 76 and the insulating layer 85 are disposed between the multilayer body 100 and the antenna substrate 300. The conductive paste layers 75 and 76 are disposed on the electrodes 71 and 72, respectively, by coating or the like. The conductive paste layers 75 and 76 ensure conductivity between the electrode 71, 72 of the antenna substrate 300 and the magnetic layer 3 of the multilayer body 100, and secure the multilayer body 100 to the antenna substrate 300 by adhesion. The insulating layer 85 protects the CPW antenna 8, and insulates the CPW antenna 8 from the multilayer body 100.

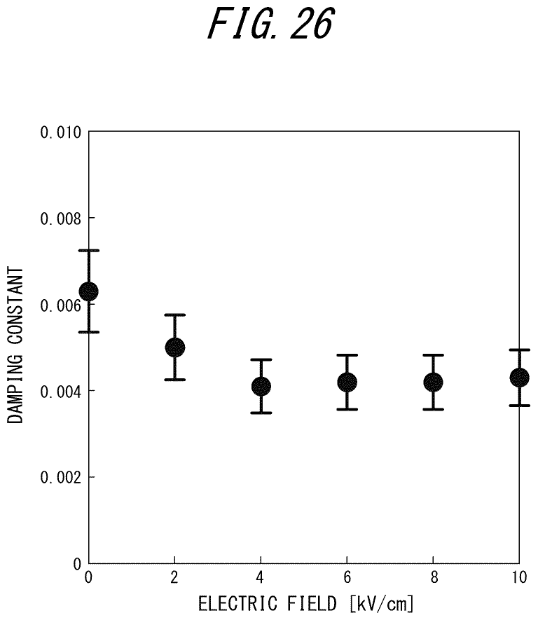

The variations in the damping constant with respect to electric field intensity were measured as follows. With an external magnetic field applied along the extension direction of the CPW antenna 8, a ferromagnetic resonance spectrum was measured through the CPW antenna 8 while varying the electric field intensity acting on the multilayer body 100 by varying a voltage to be applied between the electrode 73 on a back surface of the piezoelectric layer 1 and the electrode 71 of the antenna substrate 300. Here, an electric field acting on the multilayer body 100 was applied to a direction along a virtual plane that contains a direction along a plane surface (in-plane direction) of the magnetic layer 3 and perpendicular to the extension direction of the CPW antenna 8 and a direction perpendicular to the plane surface of the magnetic layer 3. In this measurement, the electrode 71 and the electrode 72 were set at an equal potential. Then, the damping constant of the multilayer body 100 was calculated from the line width of the ferromagnetic resonance spectrum. FIG. 26 illustrates a graph of the damping constant with respect to electric field intensity, calculated by this measurement. In FIG. 26, the horizontal axis represents the electric field intensity as electric field (kV/cm), and the vertical axis represents the damping constant (-).

As illustrated in FIG. 26, variations in the damping constant of the multilayer body 100 of the element 400 illustrated in FIG. 25 were observed due to variations in the electric field intensity (presence or absence of electric field application). Specifically, a phenomenon in which the damping constant of the multilayer body 100 decreases when the electric field intensity is increased was observed. That is, in the element 400, it is seen that the damping constant of the magnetic layer 3 can be modulated by switching the state of the electric field through the electrodes 71 and 73. This result means that the degree of attenuation of a spin wave propagating through the epitaxial ferromagnetic Heusler alloy thin film (magnetic layer 3) can be controlled by the electric field acting thereon, in other words, it means that the basic operation of a magnon transistor has been demonstrated. As illustrated in FIG. 26, in this example, it was possible to observe modulation of the order of a reduction in the damping factor by 30%, using an electric field of 1/10 or less of the dielectric breakdown electric field (~100 kV/cm) of the LiNbO₃, which was used as the piezoelectric layer 1.

As described above, it is possible to provide a multilayer body, an element, and a method of producing the multilayer body.

### Another Embodiment

(1) In the above embodiment, the multilayer body 100 has been described as being formed of the piezoelectric layer 1, the metal layer 2, and the magnetic layer 3 stacked in this order. The multilayer body 100 has been described as being able to be produced by the production method including the metal layer formation process in which the metal layer 2 is formed on the piezoelectric layer 1 and the magnetic layer formation process in which the magnetic layer is formed on the metal layer 2. However, in the multilayer body 100, the piezoelectric layer 1 before the metal layer 2 or the like is formed does not need to be a single layer (for example, substrate). For example, in the multilayer body 100, the piezoelectric layer 1 may be formed on another substrate, for example, a silicon substrate.

(2) In the above embodiment, the electrode layers 63 and 64, which are a pair of electrodes (gate), have been exemplarily described as being arranged on the sides of one end (third end) and the other end (fourth end) of the rectangular magnetic layer 3 in the lateral direction. However, the arrangement of the gate is not limited to the above example. The arrangement of the gate can be changed as appropriate depending on the structure and application of the element.

Note that, the embodiment disclosed in this specification is merely examples, and the embodiment of the present disclosure is not limited thereto, and can be appropriately modified within confines not departing from the purpose of the present disclosure.

### INDUSTRIAL APPLICABILITY

The present disclosure is applicable to a multilayer body, an element including the multilayer body, and a method of producing the multilayer body.

### REFERENCE SIGNS LIST

1 piezoelectric layer
100 multilayer body
2 metal layer
200 element
3 magnetic layer
300 antenna substrate
4 insulating layer
61 electrode layer
62 electrode layer
63 electrode layer
64 electrode layer
7 silicon substrate
70 silicon layer
70a oxide film
71 electrode
71a titanium layer
71b gold layer
72 electrode
72a titanium layer
72b gold layer
73 electrode
73a titanium layer
73b gold layer
75 conductive paste layer
76 conductive paste layer
8 CPW antenna
81 conductor
81a titanium layer
81b gold layer
82 conductor
82a titanium layer
82b gold layer
83 conductor
83a titanium layer
83b gold layer
85 insulating layer

1. A multilayer body comprising:
a piezoelectric layer made of a crystal of an oxide having piezoelectricity;
a metal layer; and
a magnetic layer made of a crystal of a Heusler alloy that is a ferromagnetic material,
wherein the piezoelectric layer, the metal layer, and the magnetic layer are stacked in this order.

2. The multilayer body according to claim 1, wherein the magnetic layer has a magnetization of 600 emu/cm³ or more.

3. The multilayer body according to claim 1, wherein the magnetic layer has a damping constant of 1.0×10⁻² or less.

4. The multilayer body according to claim 1, wherein the magnetic layer has a damping constant of 5.0×10⁻³ or less.

5. The multilayer body according to claim 1, wherein the Heusler alloy is Co₂FeSi, Co₂Fe(Si, Al), Co₂MnSi, Co₂(Fe, Mn)Si, Co₂MnGa, or Fe₃Si.

6. The multilayer body according to claim 1, wherein the Heusler alloy is Co₂FeSi.

7. The multilayer body according to claim 1, wherein
the piezoelectric layer contains a compound represented by a chemical formula ABO₃, as the oxide,
A is a metal element, and
B is one or more metal elements different from A.

8. The multilayer body according to claim 1, wherein the piezoelectric layer contains, as the oxide, one or more selected from a group consisting of quartz crystal, lithium niobate, and lithium tantalate.

9. The multilayer body according to claim 1, wherein the oxide is lithium niobate.

10. The multilayer body according to claim 1, wherein the metal layer includes a layer of a metal that is a body-centered cubic crystal at room temperature, and is a layer with a thickness of 3 nm or more.

11. The multilayer body according to claim 1, wherein
the oxide is lithium niobate,
the metal layer is configured to include a layer of at least one metal selected from a group consisting of Fe, Cr, and V, and is a layer of 10 nm or more.

12. The multilayer body according to claim 11, wherein the piezoelectric layer has an average content of a metal element constituting the metal layer of 5 at % or less, within a range of 10 nm from an interface with the metal layer.

13. The multilayer body according to claim 11, wherein the metal layer has an average content of oxygen of 5 at % or less.

14. An element comprising:
a piezoelectric layer made of a crystal of an oxide having piezoelectricity;
a metal layer; and
a magnetic layer made of a crystal of a Heusler alloy that is a ferromagnetic material,
wherein
the piezoelectric layer, the metal layer, and the magnetic layer are stacked in this order,
the metal layer has
a thickness of 10 nm or more and 40 nm or less, and
an average content of oxygen of 5 at % or less, and
the piezoelectric layer has an average content of a metal element constituting the metal layer of 5 at % or less, within a range of 10 nm from an interface with the metal layer.

15. The element according to claim 14, wherein
the oxide is lithium niobate, and
the Heusler alloy is Co₂FeSi.

16. A method of producing a multilayer body comprising:
a metal layer formation process in which a metal layer is formed on or above a piezoelectric layer made of a crystal of an oxide having piezoelectricity; and
a magnetic layer formation process in which a magnetic layer made of a crystal of a Heusler alloy that is a ferromagnetic material is formed on or above the metal layer,
wherein in the magnetic layer formation process,
by molecular beam epitaxy,
the magnetic layer is formed at a growth temperature of 80° C. or more and 450° C. or less.

17. The method of producing a multilayer body according to claim 16, wherein the oxide is lithium niobate.

18. The method of producing a multilayer body according to claim 16, wherein the Heusler alloy is Co₂FeSi.

19. The method of producing a multilayer body according to claim 16, wherein in the metal layer formation process,
by molecular beam epitaxy,
the metal layer is formed at a growth temperature of 80° C. or more and 450° C. or less.
